(19) United States
(12) Patent Application Publication
(10) Pub. No.: US 2026/0022079 A1
(43) Pub. Date: Jan. 22, 2026

(54) SELECTIVE ETCH OF TITANIUM CARBIDE MATERIALS USING OXIDATION

(71) Applicant: Tokyo Electron Limited, Tokyo (JP)

(72) Inventors: Wenyi Xie, Albany, NY (US); Ivo Otto, IV, Albany, NY (US); Kandabara Tapily, Albany, NY (US); Matthew Flaugh, Albany, NY (US); Subhadeep Kal, Albany, NY (US)

(21) Appl. No.: 18/775,333

(22) Filed: Jul. 17, 2024

(51) Int. Cl. C04B 41/53; C04B 35/56; C04B 41/00

(52) U.S. Cl. CPC C04B 41/5346; C04B 35/5611; C04B 41/0054; C04B 41/5392

(57) ABSTRACT

A method of dry etching a titanium carbide material of a substrate includes performing an oxidation step and a fluorination step. The oxidation step includes exposing the titanium carbide material to an oxidizing agent to form an oxidized layer including titanium oxide species and remove carbon from the titanium carbide material by forming volatilized carbon oxide species. The fluorination step includes exposing the titanium oxide species of the oxidized layer to a fluorinating agent to remove titanium from the titanium carbide material by forming volatilized fluorinated titanium oxide species. The method may be repeated as a cycle in situ within a processing chamber. The method may further include a substitution step that includes exposing a metallic fluoride species formed during the fluorination step to a substitution agent to remove metallic species from the titanium carbide material by forming volatilized metallic fluoride species.

### TECHNICAL FIELD

The present invention relates generally to etching processes, and, in particular embodiments, to systems and methods for selectively etching titanium carbide materials.

### BACKGROUND

Electronic device fabrication, such as microscale or nanoscale devices fabricated as integrated circuits using semiconductor processing methods, typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet etching or dry etching techniques may be used, with wet etching techniques using wet chemicals as etchants and dry etching techniques using one or both of gas phase and plasma phase etchants. Some examples of dry etching techniques are gas phase etches, remote plasma etches, and direct plasma etches.

As devices become smaller and more complex, etch requirements become more demanding. For example, it can be difficult to overcome challenges of advanced technology nodes, such as high aspect ratio features and stringent etch selectivity requirements. Moreover, advanced technology nodes are making use of materials that were not used in previous technology nodes as well as using materials that have been used before, but are now being used in new structures and contexts.

Titanium carbide (TiC) materials represent one category of materials that is finding use in advanced technology nodes. TiC materials include titanium carbide and also materials that have titanium and carbon as well as other components, such as a secondary metallic component (materials with the formula TiMC, where M is a metallic component). Conventional etching processes for TiC materials use wet etching techniques or plasma-based etching techniques, both of which suffer from insufficient selectivity and pattern fidelity. In the case of wet etches, the fine pattern features are prone to collapse when a wet chemical etchant is introduced. For plasma-based etches, pattern features can be undesirably damaged by high-energy and/or highly corrosive plasma species.

Therefore, improved etching processes that selectively and controllably etch titanium carbide materials may be desirable.

### SUMMARY

In accordance with an embodiment of the invention, a method of dry etching a titanium carbide material of a substrate includes performing a cycle in situ within a processing chamber where the cycle includes performing an oxidation step and a fluorination step. The oxidation step includes exposing the titanium carbide material to an oxidizing agent to form an oxidized layer including titanium oxide species and remove carbon from the titanium carbide material by forming volatilized carbon oxide species. The fluorination step includes exposing the titanium oxide species of the oxidized layer to a fluorinating agent to remove titanium from the titanium carbide material by forming volatilized fluorinated titanium oxide species.

In accordance with another embodiment of the invention, a method of dry etching a titanium carbide material including titanium, carbon, and a metallic species includes performing an oxidation step that includes exposing the titanium carbide material to an oxidizing agent to form an oxidized layer and removing carbon from the titanium carbide material by forming volatilized carbon oxide species. The oxidized layer includes titanium oxide species and oxidized metallic species. The method further includes performing a fluorination step that includes exposing the titanium oxide species and the oxidized metallic species of the oxidized layer to a fluorinating agent to form metallic fluoride species as well as removing titanium from the titanium carbide material by forming volatilized fluorinated titanium oxide species. The method also includes performing a substitution step that includes exposing the metallic fluoride species to a substitution agent to remove the metallic species from the titanium carbide material by forming volatilized metallic fluoride species. The method is performed in situ within a processing chamber.

In accordance with still another embodiment of the invention, a dry etching system includes a processing chamber configured to contain a substrate that includes a titanium carbide material, an oxidation source fluidically coupled to the processing chamber and configured to supply an oxidizing agent into the processing chamber, a fluorination source fluidically coupled to the processing chamber and configured to supply a fluorinating agent into the processing chamber, and a controller operationally coupled to the oxidation source and the fluorination source. The controller includes a processor and a non-transitory computer-readable medium storing a program including instructions that, when executed by the processor, perform a cycle in situ within the processing chamber. The cycle includes an oxidation step that includes exposing the titanium carbide material to the oxidizing agent to form an oxidized layer including titanium oxide species and removing carbon from the titanium carbide material by forming volatilized carbon oxide species. The cycle also includes a fluorination step that includes exposing the titanium oxide species of the oxidized layer to the fluorinating agent to remove titanium from the titanium carbide material by forming volatilized fluorinated titanium oxide species.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example dry etching process schematically showing an initial state of a substrate including a titanium carbide (TiC) material, the example dry etching process including an oxidation step to form titanium oxide (TiOₓ) species and a fluorination step to remove the TiOₓ species as volatilized fluorinated species in accordance with embodiments of the invention;

FIG. 2 illustrates an example dry etching process schematically showing an initial state of a substrate including a TiC material that has a secondary metallic component M, the example dry etching process including an oxidation step to form TiOₓ species and oxidized metallic (MOₙ) species, a fluorination step to remove the TiOₓ species as volatilized fluorinated species and form metallic fluoride (MFₙ) species, and a substitution step to remove the MFₙ species as volatilized MFₙ species in accordance with embodiments of the invention;

FIG. 3 illustrates an example dry etching process that includes an oxidation step, a fluorination step, and a substitution step where the TiC material is a titanium aluminum carbide (TiAlC) material in accordance with embodiments of the invention;

FIG. 4 illustrates an example dry etching process that includes an oxidation step, a fluorination step, and a substitution step where the TiC material is a titanium lanthanum carbide (TiLaC) material in accordance with embodiments of the invention;

FIG. 5 illustrates an example dry etching process schematically showing an initial state of a substrate that includes a TiC material and titanium nitride (TiN) where the TiC material is selectively etched in accordance with embodiments of the invention;

FIG. 6 schematically illustrates an example dry etching system that may be used to perform etching processes including at least an oxidation step and a fluorination step to etch TiC materials in situ within a processing chamber in accordance with embodiments of the invention; and

FIG. 7 illustrates an example method of dry etching a titanium carbide material in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Titanium carbide (TiC) materials are finding uses in electronic device fabrication, such as in memory applications in advanced technology nodes (5 nm, 3 nm, etc.). For example, TiMC materials that include a secondary metallic component M, such as aluminum (Al), lanthanum (La), silicon (Si), and others, may be used as a work function metal in logic chips. In advanced technology nodes, (e.g., due to high aspect ratio features and stringent etch selectivity requirements), etching TiC materials is becoming extremely challenging. For example, the TiC:TiN etch selectivity (and in particular, TiMC:TiN etch selectivity) may be important for advanced devices, such as for multiple threshold voltage (multi-Vt) modulation in gate-all-around (GAA) devices.

Conventional etching processes use wet etching techniques and plasma-based etching techniques to etch TiC materials. However both wet and plasma-based etching techniques suffer from challenges, such as selectivity, pattern damage (primarily from the use of plasma and in some cases, remote plasma) and pattern collapse (primarily from the use of wet chemicals). Furthermore, in the specific case of etching TiC materials in the presence of TiN, conventional etching processes lack the required TIC:TiN etch selectivity.

In accordance with embodiments herein described, the invention proposes a dry etching process that selectively etches TiC materials using an oxidation step followed by a fluorination step. When a secondary metallic component is included (i.e., the TiC material is a TiMC material), a substitution step is also included after the fluorination step and the dry etching process is a sequential 3-step process. In various embodiments, the dry etching process is a cyclic process performed in situ (i.e., in place) within a single processing chamber.

During the oxidation step, the TiC material is exposed to an oxidizing agent, such as gaseous ozone O₃(g), to form an oxidized layer with titanium oxide (TiOₓ) species. The oxidizing agent also removes carbon from the TiC material by forming volatilized carbon oxide species (CO, CO₂, etc.). Following the oxidation step, the TiOₓ species are exposed to a fluorinating agent, such as gaseous hydrogen fluoride HF(g), during the fluorination step forming volatilized fluorinated titanium oxide (TiOₓF_{y}) species that removes titanium from the TIC material.

When the TiC material is a TiMC material, which may be titanium aluminum carbide (TiAlC), titanium silicon carbide (TiSiC), titanium lanthanum carbide (TiLaC), and others, the metallic component M is removed during the substitution step. Specifically, the oxidizing agent also forms oxidized metallic (MOₙ) species during the oxidation step that are then fluorinated during the fluorination step to form metallic fluoride (MFₙ) species remaining at the surface. During the substitution step, the MFₙ species are exposed to a substitution agent, such as trimethylaluminum Al(CH₃)₃, forming volatilized MFₙ species that removes the metallic species (e.g., Al, Si, La, etc.) from the TiC material.

The dry etching processes described herein may have various advantages over conventional TiC etching processes. For example, the dry etching processes may have improved etch selectivity and control over etch selectivity of TiC materials relative to TiN (including both TiC and other TiC-based materials, such as TiMC materials, where M is a metallic component; TiC:TiN etch selectivity and TiMC:TiN etch selectivity). For example, the oxidation step of the herein described dry etching processes may advantageously enable etch selectivity of TIC materials relative to TiN (e.g., by enabling reactions of subsequent steps for the TiC material, but not for TiN). This selectivity between TiC materials and TiN may be desirable for various applications, including multi-Vt modulation in GAA devices, for example. Additionally, the dry etching processes may have the benefit of improved control over etch rate (e.g., through control of the sequential surface reactions). The dry etching processes may also produce a uniform, isotropic etch front.

As a dry etch, the embodiment etching processes may have improved pattern fidelity over conventional processes. One specific example may be advantageously avoiding pattern collapse that is common in conventional wet titanium carbide etching processes. Some of all of the steps of the embodiment dry etching processes may also be thermal processes (e.g., using no plasma) or may avoid direct plasma (using only remote plasma). As a result, the dry etching processes may also advantageously avoid pattern damage typical in conventional plasma-based titanium carbide etching processes. Further, all steps of the dry etching processes may have the benefit of being performed in a single chamber in one platform.

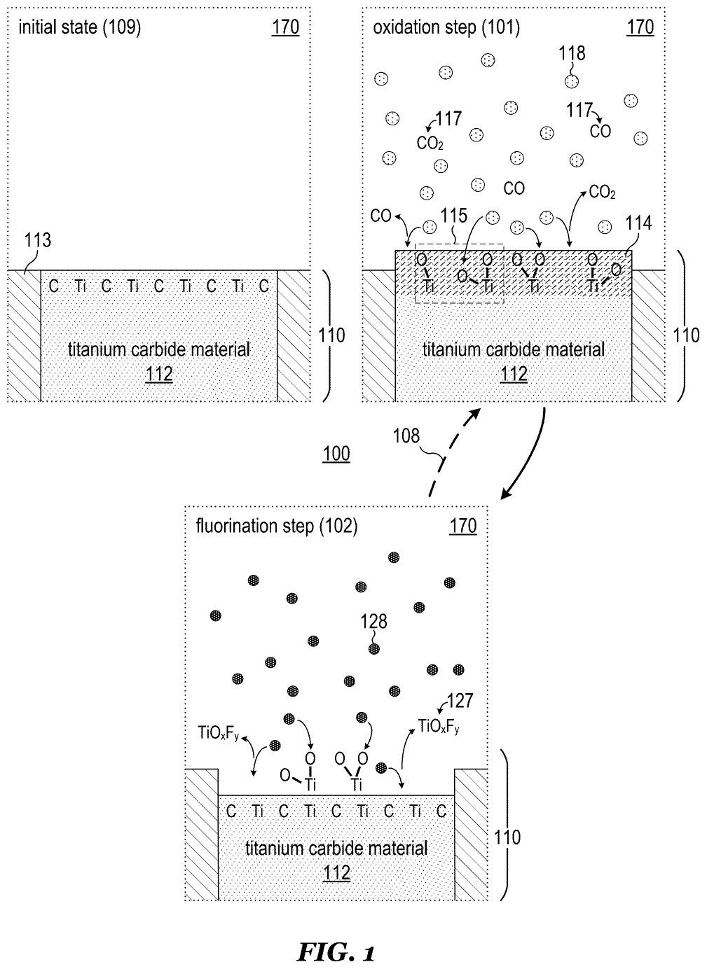

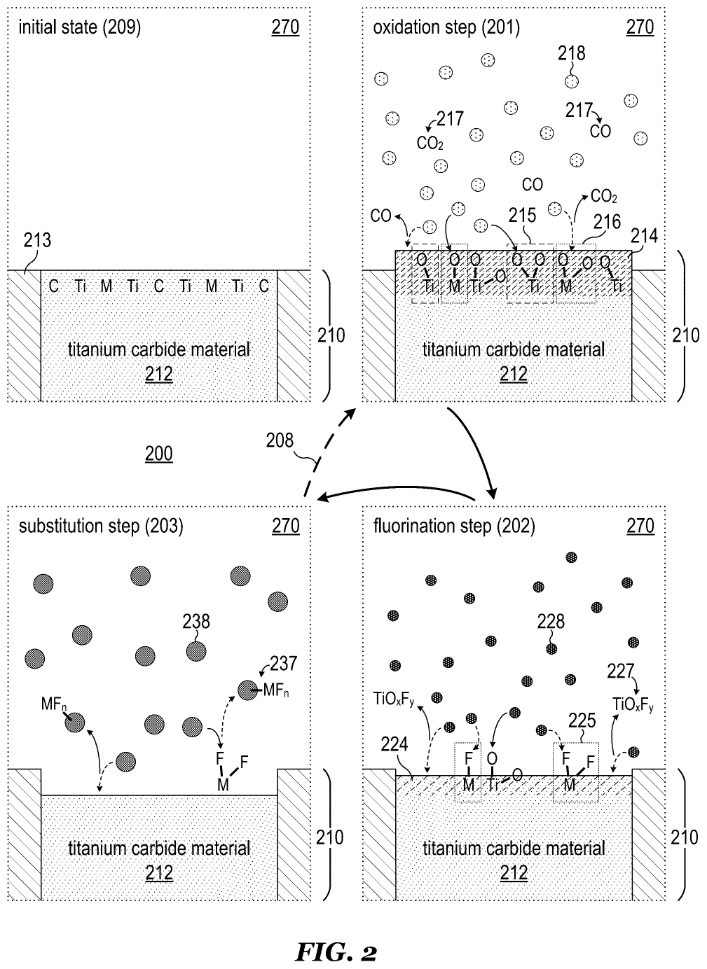

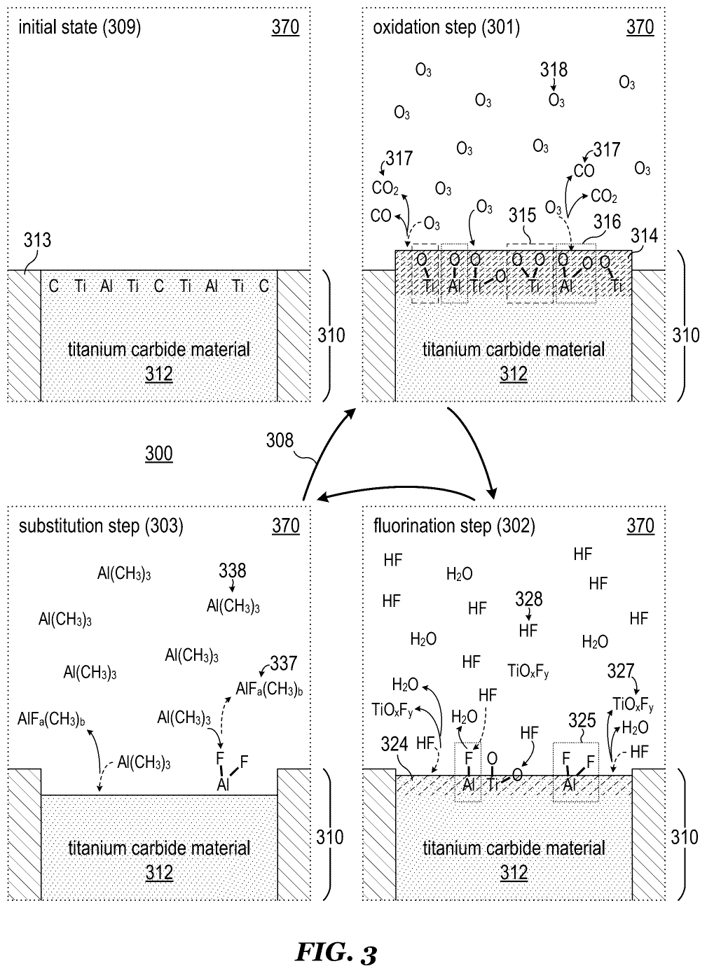

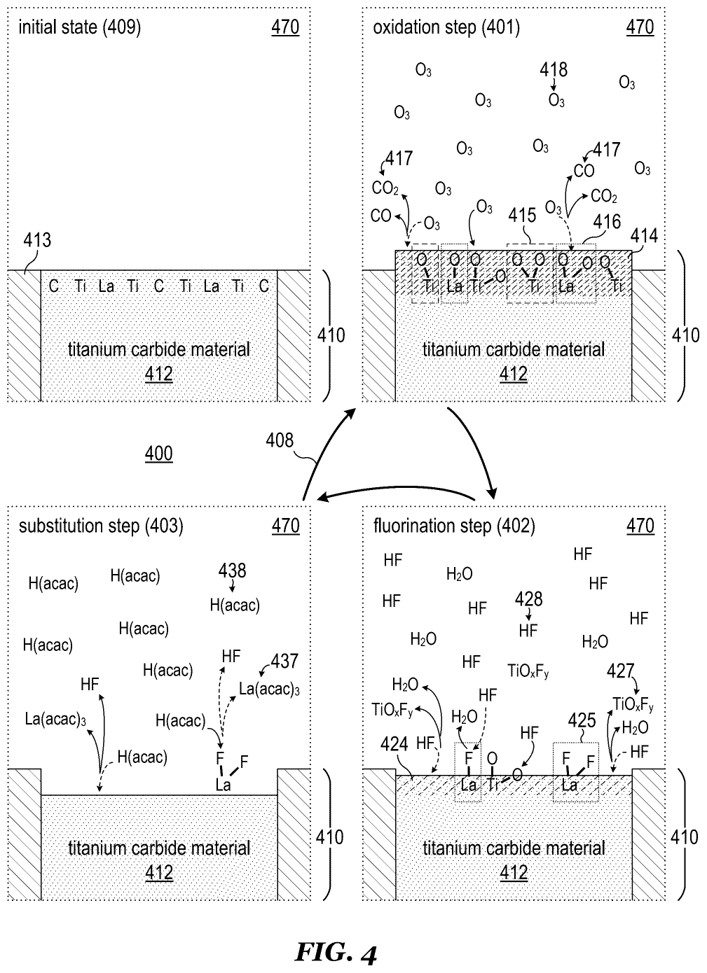

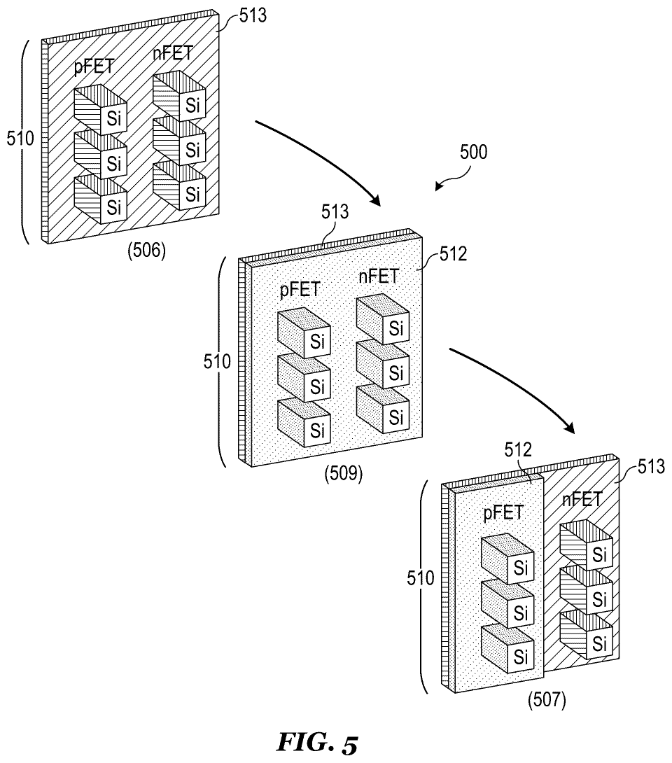

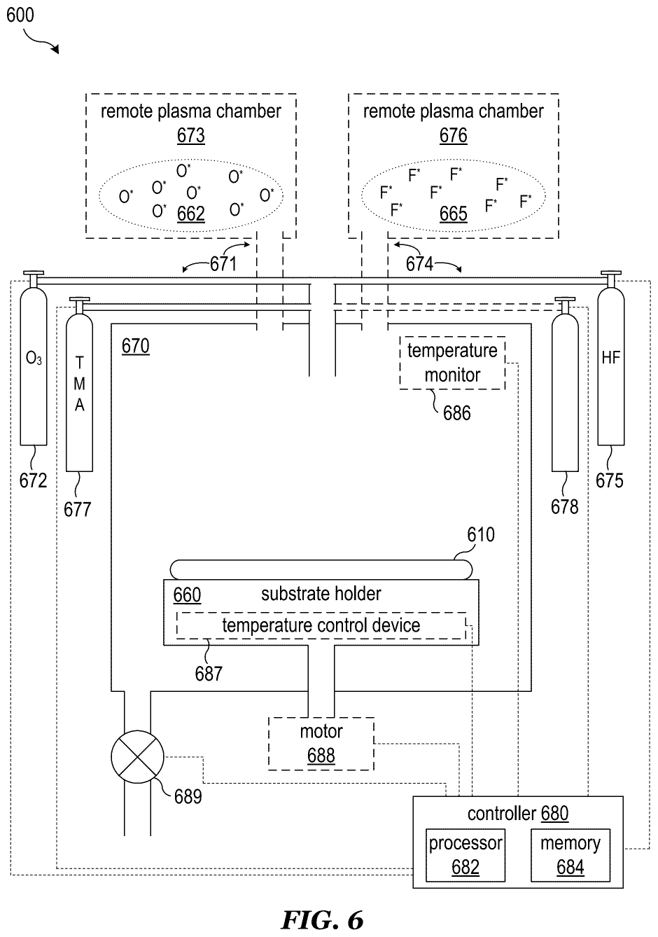

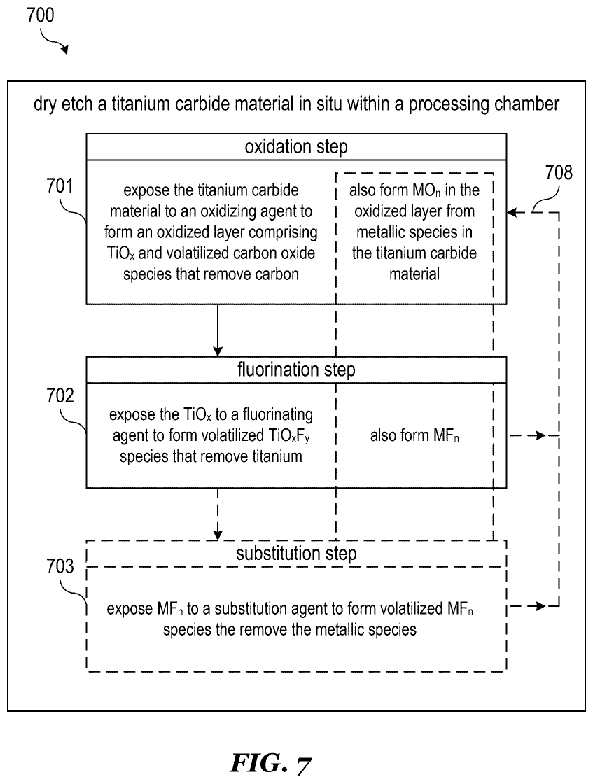

Embodiments provided below describe various methods and systems for dry etching a TiC material, and in particular embodiments, to systems and methods for selectively dry etching a TiC material that include at least an oxidation step and a fluorination step. The following description describes the embodiments. FIG. 1 is used to describe an example dry etching process that includes an oxidation step and a fluorination step. FIG. 2 is used to describe an example dry etching process where the TiC material includes a secondary metallic component and the dry etching process also includes a substitution step. Two more example dry etching processes are described using FIGS. 3 and 4. An example etching process as applied to a specific application is described using FIG. 5. FIG. 6 is used to describe an example dry etching system while FIG. 7 is used to describe an example method of etching a TiC material.

FIG. 1 illustrates an example dry etching process schematically showing an initial state of a substrate including a TiC material, the example dry etching process including an oxidation step to form TiOₓ species and a fluorination step to remove the TiOₓ species as volatilized fluorinated species in accordance with embodiments of the invention.

Referring to FIG. 1, a dry etching process 100 includes an oxidation step 101 and a fluorination step 102 (and may include other steps, as will be discussed in detail in this following examples). An initial state 109 of a substrate 110 is schematically shown in a processing chamber 170 at the top left. The substrate 110 includes a TiC material 112 (a titanium carbide material that is the target material of the dry etching process 100) as well as a secondary material 113 (any other material that is not an etch target, such as a nitride material like TiN, for example).

The exact composition and configuration of the secondary material 113 may vary depending on the specific details of a given application. For example, on the substrate 110, the secondary material 113 is shown as being on either side of the TiC material 112. However, in other implementations, the secondary material 113 may be beneath the TiC material 112. Of course, any structure is possible as long as there are exposed surfaces of the TiC material 112. Additional secondary materials may also be included.

The TiC material 112 may be any material including titanium and carbon in any stoichiometric ratio. In one embodiment, the TiC material 112 is TiC (i.e., a substantially 1:1 stoichiometric ratio). In other embodiments, additional secondary components may be included in the TiC material 112, such as one or more secondary metallic components M (indicated by the label TiMC throughout) in some embodiments. Of course, the exact stoichiometric ratio of the titanium and the carbon to the secondary components may also vary as desired and is not limited any one ratio for any given secondary material.

The substrate 110 may include other materials than the TiC material 112 and the secondary material 113. For example, the substrate 110 may be any suitable substrate, such as an insulating, conducting, or semiconducting substrate with one or more layers (e.g., layers that include the TiC material 112 and the secondary material 113, among other materials) disposed thereon. For example, the substrate 110 may be a semiconductor wafer, such as a silicon wafer, and include various layers, structures, and devices (e.g., forming integrated circuits). In one embodiment, the substrate 110 includes silicon. In another embodiment, the substrate 110 includes silicon germanium (SiGe). In still another embodiment, the substrate 110 includes gallium arsenide (GaAs). Of course, many other suitable materials, semiconductor or otherwise, may be included in the substrate 110 as may be apparent to those of skill in the art.

The processing chamber 170 may be any suitable chamber configured to contain the substrate 110 in a position suitable for the dry etching process 100. In various embodiments, the processing chamber 170 is a dry etching chamber configured to hold one or more process gases (e.g., the oxidizing agent 118, the fluorinating agent 128, and others, in gas or plasma phases), but is not configured to produce a direct plasma during the dry etching process 100. In one embodiment, the processing chamber 170 is configured to facilitate only gas phase reactions (e.g., under vacuum introducing process gases entirely in the gas phase under controlled process conditions). In other embodiments, one or more process gases may be provided into the processing chamber 170 partially or entirely in the plasma phase (e.g., formed in a remote plasma chamber and introduced into the processing chamber 170 through fluidic coupling).

During the oxidation step 101, an oxidizing agent 118 is introduced (e.g., flowed, diffused, or otherwise provided) into the processing chamber 170. In various embodiments, the oxidizing agent 118 is in the gas phase. In other embodiments, the oxidizing agent 118 may be in partially or entirely in the plasma phase, such as being sourced from a remote plasma. Notably, the oxidizing agent 118 is not a direct plasma, which may have various advantages, such as avoiding damage to patterned layers serving as etch masks, improving selectivity of the oxidation step to the TiC material 112 (e.g., relative to the secondary material 113), avoiding the use of plasma etching equipment, enabling the dry etching process 100 to be performed in situ in the processing chamber 170, etc.

The oxidizing agent 118 may be any suitable oxygen-containing compound. In some embodiments, the oxidizing agent 118 includes ozone gas O₃(g) and is pure O₃(g) in one embodiment. In various embodiments, the oxidizing agent 118 includes dioxygen gas O₂(g), and is pure O₂(g) in one embodiment, and includes remote O₂ plasma species in other embodiments. Other elements than oxygen may also be included in the oxidizing agent 118, such as hydrogen and/or carbon. For example, the oxidizing agent 118 may include hydrogen peroxide gas H₂O₂(g), water vapor H₂O(g) (including remote H₂O plasma), carbon dioxide gas CO₂(g), carbon monoxide gas CO(g), and others. The oxidizing agent 118 may also be a combination of oxygen-containing gases in some cases. In some implementations, additional gas phase components may also be included along with the oxidizing agent 118, such as one or more inert gases (e.g., used as diluent, purge, and/or carrier gases). Such gases may include dinitrogen gas N₂(g), argon gas Ar(g), helium gas He(g), neon gas (Ne), and others.

The oxidizing agent 118 reacts with the surface (or surface layer) of the TiC material 112 and forms an oxidized layer 114 (i.e., a surface layer) that includes TiOₓ species 115 (titanium oxide species). In some cases, additional oxide species may also be formed, such as when a secondary metallic component is included in the TiC material 112.

In addition to the TiOₓ species 115, volatilized carbon oxide species 117 are also formed that remove carbon from the TiC material 112 as a result of being in a volatilized state (i.e. gas phase). For example, carbon monoxide (CO) and/or carbon dioxide (CO₂) may be formed (as shown), but of course the exact chemical formulations of the volatilized carbon oxide species 117 is not limited to any particular compound or group of compounds and may depend on the choice of oxidizing agent 118, among other factors.

The oxidized layer 114 is schematically shown as extending higher than the secondary material 113 (i.e., having more material than in the initial state 109) to indicate that oxygen is being added to the TiC material 112 (i.e., oxidation) during the oxidation step 101. However, material is also being removed during the oxidation step 101 (specifically carbon). Therefore, whether more or less volume of the TiC material 112 is actually present after the oxidation step 101 may depend on the specific details of the TiC material 112 and the oxidizing agent 118, as well as process conditions. Further, surfaces are illustrated as being flat for conceptual purposes, while in reality the surfaces (especially etched surfaces of the TiC material 112) may have some degree of topography due to the etching process.

The secondary material 113 is not significantly affected by the oxidation step 101, which may be a benefit for preventing subsequent reactions with the secondary material 113 from occurring during the dry etching process 100. That is, the oxidation step 101 neither removes significant material from the secondary material 113 nor does it enable significant reactivity to future species introduced to continue the etching process of the TiC material 112. Moreover, the choice of the oxidizing agent 118 and the process parameters during the oxidation step 101 may be changed to modulate the etch selectivity of the dry etching process 100.

The process conditions during the oxidation step 101 may vary depending on the specific details of a given application. The oxidation step 101 may be performed at a pressure at the low end of the low vacuum regime. In various embodiments, the oxidation step 101 is performed at a pressure on the order of 5 Torr (e.g., about 1 Torr to about 9 Torr) and is performed at about 3 Torr in some embodiments. The oxidation step 101 may be performed at a relatively low temperatures, such as at a temperature in the thermal processing range (e.g., about room temperature of 25° C. to about 300° C.). In some embodiments, the oxidation step 101 is performed at a temperature of about 250° C., and is performed at a temperature of about 250° C. and a pressure of about 3 Torr in one embodiment.

The oxidation step 101 may be diffusion limited in that the thickness of the oxidized layer 114 is limited by the ability of the oxidizing agent 118 to diffuse into the TiC material 112 and the oxidized layer 114 as it forms resulting in a self-limiting quality. The thickness of the oxidized layer 114 (and therefore the amount of material ultimately etched away from the TIC material 112 during the oxidation step 101 and the fluorination step 102) may be advantageously modulated with temperature and pressure. Additionally, the degree to which the oxidation step 101 has any effect on the secondary material 113 may also be modulated through appropriate choices of both the oxidizing agent 118 and the process conditions.

During the fluorination step 102, a fluorinating agent 128 is introduced (e.g., flowed, diffused, or otherwise provided) into the processing chamber 170. Similar to the oxidizing agent 118, the fluorinating agent 128 is in the gas phase during the fluorination step 102 in various embodiments. However, the fluorinating agent 128 may also be partially or entirely in the plasma phase, such as being sourced from a remote plasma. Again, the oxidizing agent 118 is not a direct plasma, which may offer similar advantages as those already discussed.

The fluorinating agent 128 may be any suitable fluorine-containing compound or mixture of compounds in the gas phase, plasma phase, or a mixture thereof. In some embodiments, the fluorinating agent 128 includes hydrogen fluoride gas HF(g) and is pure HF(g) in one embodiment. Fluorine-containing compounds that include additional non-metal components other than hydrogen may also be used. In one embodiment, the fluorinating agent 128 includes sulfur hexafluoride gas SF₆(g). Other examples include sulfur tetrafluoride SF₄(g), silicon tetrafluoride SiF₄(g), gaseous xenon fluorides, such as XeF₂(g), XeF₄(g), and XeF₆(g), as well as other non-metal fluorides. In other implementations, metal fluorides, such as tungsten hexafluoride gas WF₆(g) or molybdenum hexafluoride gas MoF₆(g) may also be used. However, metal components may become contaminants during the dry etching process 100, making metal fluorides less desirable in some applications.

In some cases, it may be advantageous for the fluorinating agent 128 to only include substantially unreactive components alone with fluorine to prevent unwanted reactions and/or contamination. For this reason, gaseous xenon fluorides may be advantageous in some cases. In other cases, it may be desirable for components other than fluorine included in the fluorinating agent 128 to undergo side reactions that further the goals of the dry etching process 100. For example, in the specific example of HF(g) used as the fluorinating agent 128, water vapor H₂O(g) may be formed along with the fluorinated species, thereby carrying away excess oxygen along with the hydrogen. As with the oxidizing agent 118, additional gas phase components may also be included along with the fluorinating agent 128, such as one or more inert gases (e.g., used as diluent, purge, and/or carrier gases).

The fluorinating agent 128 reacts with the surface (or surface layer) of the TiC material 112, which is now the oxidized layer 114 formed during the oxidation step 101. Reactions between the TiOₓ species 115 and the fluorinating agent 128 form volatilized TiOₓF_{y} species 127 that remove titanium from the TiC material 112. As before, the exact chemical formulation of the volatilized TiOₓF_{y} species 127 is not limited to any particular compound or group of compounds and may depend on the choice of fluorinating agent 128, in addition to other factors.

Along with the volatilized TiOₓF_{y} species 127, other fluorinated species may also be formed during the fluorination step 102, whether volatilized or remaining at the surface layer (i.e., nonvolatile) of the TiC material 112. For example, when a secondary metallic component is included in the TiC material 112, metallic fluoride species may be formed, and may remain at the surface layer. In various embodiments, the dry etching process 100 may include additional process steps (such as a substitution step) to remove the metallic fluoride species as will be described in more detail in future examples.

The process conditions during the fluorination step 102 may also vary depending on the specific details of a given application. For example, the process conditions during the fluorination step 102 may vary between similar ranges of temperature and pressure as previously discussed for the oxidation step 101. In various embodiments, one or both of the temperature and pressure during the fluorination step 102 may be the same as that of the oxidation step 101. For instance, background gases may be flowed along with the oxidizing agent 118 and the fluorinating agent 128 and the process conditions may advantageously be kept substantially constant between steps while the flowrate of the oxidizing agent 118 and the fluorinating agent 128 are modulated to perform a given step.

In various embodiments, the dry etching process 100 is a thermally driven etching process, which may be performed with or without remote plasma during each of the processing steps. For example, the combination of the oxidation step 101 and the fluorination step 102 may advantageously be performed entirely in the gas phase and therefore function as a purely gas phase etch. Alternatively, remote plasma may be used in one or both of the oxidation step 101 and the fluorination step 102, but no direct plasma is used in the dry etching process 100. Additionally, the dry etching process 100 is an isotropic etching process, which results in a uniform etch front (e.g., due to the controllable self-limiting nature of each step of the etching process).

The oxidation step 101 and the fluorination step 102 are performed sequentially. That is, the oxidation step 101 must occur before the fluorination step 102 with little or no overlap. In various embodiments, a purge step is included between the oxidation step 101 and the fluorination step 102 to avoid unwanted gas phase reactions between the oxidizing agent 118 and the fluorinating agent 128 (e.g., that may result in undesirable deposited species or decreased reaction efficiency, etc.). For example, during a purge step, only background gases (which may be the same as additional gases included during one or both of the oxidation step 101 and the fluorination step 102) may be flowed without reactive gases.

The combination of the oxidation step 101 and the fluorination step 102 (and other steps, if included) controllably removes some amount of the TiC material 112. In various embodiments, the desired amount of the TiC material 112 etched during the dry etching process 100 is greater than the amount of the TiC material 112 removed during a single performance of the oxidation step 101 and the fluorination step 102. Therefore, in various embodiments, all of the steps of the dry etching process 100 including the oxidation step 101 and the fluorination step 102 are repeated as part of a cycle 108 (i.e., the dry etching process 100 is a cyclic process where each iteration of the cycle 108 removes addition material from the TiC material 112).

Since the amount of the TiC material 112 that is etched away during each cycle may be controlled using process conditions and choices or one or both of the oxidizing agent 118 and the fluorinating agent 128, the total etch amount of the dry etching process 100 may advantageously be controlled with high accuracy by controlling the number of iterations of the cycle 108.

FIG. 2 illustrates an example dry etching process schematically showing an initial state of a substrate including a TiC material that has a secondary metallic component M, the example dry etching process including an oxidation step to form TiOₓ species and MOₙ species, a fluorination step to remove the TiOₓ species as volatilized fluorinated species and form MFₙ species, and a substitution step to remove the MFₙ species as volatilized MFₙ species in accordance with embodiments of the invention. The dry etching process of FIG. 2 may be a specific implementation of other dry etching processes described herein such as the dry etching process of FIG. 1, for example. Similarly labeled elements may be as previously described.

Referring to FIG. 2, a dry etching process 200 includes an oxidation step 201 and a fluorination step 202. In this specific example, the dry etching process 200 also includes a substitution step 203. It should be noted that here and in the following a convention has been adopted for brevity and clarity wherein elements adhering to the pattern [x01] where ‘x’ is the figure number may be related implementations of an oxidation step in various embodiments. For example, the oxidation step 201 may be similar to the oxidation step 101 except as otherwise stated. An analogous convention has also been adopted for other elements as made clear by the use of similar terms in conjunction with the aforementioned numbering system.

An initial state 209 of a substrate 210 is schematically shown in a processing chamber 270 at the top left. The substrate 210 includes a TiC material 212 (a titanium oxide material that is the target material of the dry etching process 200) as well as a secondary material 213, which may be a nitride material, such as TiN, for example. In this specific example, the TiC material 212 also includes a secondary metallic component M, (e.g., a metallic species, such as a metal or a metalloid, Al, Si, and La, being some examples).

During the oxidation step 201, an oxidizing agent 218 is introduced into the processing chamber 270 and reacts with the surface (or surface layer) of the TiC material 212 forming an oxidized layer 214 that is a mixed layer including TiOₓ species 215 as well as MOₙ species 216 (oxidized metallic species). As before, volatilized carbon oxide species 217 are also formed in addition to the TiOₓ species 215 that remove carbon from the TiC material 212. Notably, the secondary material 213 is again not significantly affected by the oxidation step 201, which may be beneficial for preventing subsequent reactions with the secondary material 213 from occurring during the dry etching process 200.

After the oxidation step 201, a fluorinating agent 228 is introduced into the processing chamber 270 during the fluorination step 202 and reacts with the surface (or surface layer) of the TiC material 212, which is now the oxidized layer 214 formed during the oxidation step 201. Reactions between the TiOₓ species 215 and the fluorinating agent 228 form volatilized TiOₓF_{y} species 227 that remove titanium from the TiC material 212.

Additionally, reactions between the MOₙ species 216 and the fluorinating agent 228 form MFₙ species 225 (metallic fluoride species). The MFₙ species 225 may not be volatile, resulting in the formation of a fluorinated layer 224 during the fluorination step 202 that takes the place of the oxidized layer 214. That is, at least some of the MFₙ species 225 may remain at the surface layer of the TiC material 212.

In this specific example, the dry etching process 200 also includes the substitution step 203 during which a substitution agent 238 is introduced (e.g., flowed, diffused, or otherwise provided) into the processing chamber 270. The substitution agent 238 is in the gas phase and is configured to react with the MFₙ species 225 of the fluorinated layer 224 to form volatilized MFₙ species 237. Specifically, the substitution agent 238 is configured to undergo what may broadly considered substitution reactions with the MFₙ species 225 so that volatile compounds including M and F are formed and carried away from the TiC material 212 in the gas phase.

The substitution agent 238 may be any suitable compound, the composition of which may depend on the specific details of a given application. In various embodiments, the substitution agent 238 includes an organometallic compound, and is trimethylaluminum gas Al(CH₃)₃(g), which may in some cases exists as a dimer Al₂(CH₃)₆(g), also abbreviated as TMA. For example, TMA gas may be advantageous as a component of the substitution agent 238 due to reactivity with metal halides, such as the MFₙ species 225 that are formed in the fluorination step 202. In particular, TMA gas may undergo substitution reactions (which be more specifically termed ligand exchange reactions) with the MFₙ species 225 As with oxidizing agent 218 and the fluorinating agent 228, additional gas phase components may also be included along with the substitution agent 238, such as one or more inert gases (e.g., used as diluent, purge, and/or carrier gases).

Another example of a possible category of compounds that may be included in the substitution agent 238 are diketone species, for example including acetylacetone (ACAC) species, (having the chemical formula R—C(═O)—CH₂—C(═O)—R′). The most fundamental ACAC species is unsubstituted acetylacetone CH₃—C(═O)—CH₂—C(═O)—CH₃(g). In one embodiment, the substitution agent 238 includes acetylacetone gas, which may be abbreviated as H(acac)(g), in reference to combination of the acetylacetonate anion (acac⁻) and a hydrogen ion (H⁺). Of course other ACAC species may also be used. ACAC species may have the advantage of be a chelating compound, and form volatile coordinated compounds with metals.

The process conditions during the substitution step 203 may also vary depending on the specific details of a given application. For example, the process conditions during substitution step 203 may vary between similar ranges of temperature and pressure as previously discussed for the oxidation step 201 and the fluorination step 202 (e.g., previously in reference to the oxidation step 101 and the fluorination step 102 of FIG. 1, for example). In various embodiments, one or both of the temperature and pressure during the substitution step 203 may be the same one or both of the oxidation step 201 and the fluorination step 202. Of course, the temperature and pressure during any of the steps of the dry etching process 200 may also be different from other steps, if desired.

All of the oxidation step 201, the fluorination step 202, and the substitution step 203 are performed sequentially. That is, the oxidation step 201 must occur before the fluorination step 202 and the fluorination step 202 must occur before the substitution step 203, with little or no overlap. A purge step may be included between some or all of the steps of the dry etching process 200. As before, all of the steps of the dry etching process 200 including the oxidation step 201, the fluorination step 202, and the substitution step 203 (along with any purge steps) are repeated as part of a cycle 208.

FIG. 3 illustrates an example dry etching process that includes an oxidation step, a fluorination step, and a substitution step where the TiC material is a TiAlC material in accordance with embodiments of the invention. The dry etching process of FIG. 3 may be a specific implementation of other dry etching processes described herein such as the dry etching process of FIG. 2, for example. Similarly labeled elements may be as previously described.

Referring to FIG. 3, a dry etching process 300 includes an oxidation step 301, a fluorination step 302, and a substitution step 303, which is repeated as part of a cycle 308. An initial state 309 of a substrate 310 is schematically shown in a processing chamber 370 at the top left. The substrate 310 includes a TiC material 312, which is a TiAlC material in this specific example, as well as a secondary material 313 (e.g., TiN).

During the oxidation step 301, an oxidizing agent 318, which is O₃(g) in this specific example, is introduced into the processing chamber 370 and reacts with the surface layer of the TiC material 312 forming an oxidized layer 314 that is a mixed layer including TiOₓ species 315 as well as MOₙ species 316 (here, AlOₙ species). Volatilized carbon oxide species 317, which may include at least CO(g) and CO₂(g) be virtue of the stoichiometry of the reaction between reactive carbon sites and O₃(g), are also formed.

After the oxidation step 301, a fluorinating agent 328, which is HF(g) in this specific example, is introduced into the processing chamber 370 during the fluorination step 302. The fluorinating agent 328 reacts with the oxidized layer 314 and forms TiOₓF_{y} species 327, MFₙ species 325, and H₂O(g) (e.g., from the hydrogen and oxygen of the HF(g)+MOₙ reaction). The nonvolatile MFₙ species 325 remain at the surface of the TiC material 312 as a fluorinated layer 324.

During the substitution step 303, a substitution agent 338 is introduced into the processing chamber 370. Here, the substitution agent 338 is TMA gas Al(CH₃)₃(g), which is shown as Al(CH₃)₃, indicating the dimer has been cracked, such as from provide thermal energy. The substitution agent 338 reacts with the MFₙ species 325 of the fluorinated layer 324 to form volatilized MFₙ species 337, which here are AlFₐ(CH₃)_{b} species (formed from a ligand exchange reaction, for example). It should also be noted that this same specific set of compounds may also be used with success for other secondary metallic components, such as Si, for example. However, other secondary metallic components may use different chemistry, one example of which is discussed in reference to FIG. 4.

As shown, the fluorination step 302 removes carbon from the TiAlC and prepares the remaining surface of TiC material 312 for the second reaction by forming the oxidized layer 314. The fluorination step 302 removes the titanium from the TiAlC and prepares the remaining surface of the TiC material 312 for the third reaction by forming the fluorinated layer 324. Finally, the substitution step 303 removes the aluminum from the TiAlC (as well as fluorine) leaving a previously-covered surface of the TiC material 312 which may be etched in the next iteration of the cycle 308. As mentioned in the forgoing, purge steps may be included after all of the oxidation step 301, the fluorination step 302, and the substitution step 303, such as to prevent undesirable gas phase reactions (e.g., Al₂O₃ and AlF₃ deposition resulting from simultaneous exposures of TMA/O₃ or TMA/HF).

FIG. 4 illustrates an example dry etching process that includes an oxidation step, a fluorination step, and a substitution step where the TiC material is a TiLaC material in accordance with embodiments of the invention. The dry etching process of FIG. 4 may be a specific implementation of other dry etching processes described herein such as the dry etching process of FIG. 2, for example. Similarly labeled elements may be as previously described.

Referring to FIG. 4, a dry etching process 400 includes an oxidation step 401, a fluorination step 402, and a substitution step 403, which is repeated as part of a cycle 408. An initial state 409 of a substrate 410 is schematically shown in a processing chamber 470 at the top left. The substrate 410 includes a TiC material 412, which is a TiLaC material in this specific example, as well as a secondary material 413 (e.g., TiN).

During the oxidation step 401, an oxidizing agent 418, which is O₃(g) in this specific example, is introduced into the processing chamber 470 and reacts with the surface layer of the TiC material 412 forming an oxidized layer 414 that is a mixed layer including TiOₓ species 415 as well as MOₙ species 416 (here, LaOₙ species). Volatilized carbon oxide species 417, which may include at least CO(g) and CO₂(g) be virtue of the stoichiometry of the reaction between reactive carbon sites and O₃(g), are also formed.

After the oxidation step 401, a fluorinating agent 428, which is HF(g) in this specific example, is introduced into the processing chamber 470 during the fluorination step 402. The fluorinating agent 428 reacts with the oxidized layer 414 and forms TiOₓF_{y} species 427, MFₙ species 425, and H₂O(g) (e.g., from the hydrogen and oxygen of the HF(g)+MOₙ reaction). The nonvolatile MFₙ species 425 remain at the surface of the TiC material 412 as a fluorinated layer 424. During the substitution step 403, a substitution agent 438 is introduced into the processing chamber 470. Here, the substitution agent 438 is ACAC gas H(acac)(g) and reacts with the MFₙ species 425 of the fluorinated layer 424 to form volatilized MFₙ species 437, which here are La(acac)₃ species (coordinated metal compounds of La) as well as HF(g).

As shown, the fluorination step 402 removes carbon from the TiLaC and prepares the remaining surface of TiC material 412 for the second reaction by forming the oxidized layer 414. The fluorination step 402 removes the titanium from the TiAlC and prepares the remaining surface of the TiC material 412 for the third reaction by forming the fluorinated layer 424. Finally, the substitution step 403 removes the lanthanum from the TiAlC (as well as fluorine) leaving a previously-covered surface of the TiC material 412 which may be etched in the next iteration of the cycle 408. Again, purge steps may be included after all of the oxidation step 401, the fluorination step 402, and the substitution step 403, such as to prevent undesirable gas phase reactions.

FIG. 5 illustrates an example dry etching process schematically showing an initial state of a substrate that includes a TiC material and TiN where the TiC material is selectively etched in accordance with embodiments of the invention. The dry etching process of FIG. 5 may be a specific implementation of other dry etching processes described herein such as the dry etching process of FIG. 1, for example. Similarly labeled elements may be as previously described.

Referring to FIG. 5, a dry etching process 500 begins with a substrate 510 that includes various devices, such as p-type field-effect transistor (pFET) and n-type FET (nFET) devices, as shown in this specific example. A preparation state 506 of the substrate 510 includes a secondary material 513. A TiC material 512 is formed (e.g., deposited, grown, etc.) on the substrate 510 over the secondary material 513 so that the substrate 510 is in an initial state 509. For example, the TiC material 512 may be TiC or a TiMC material (with M being Al, Si, La, or another metallic component) while the secondary material 513 may be TiN, such as when the TiC material 512 and the secondary material 513 are used as work function materials for logic applications.

At this stage it may be desirable to etch the TiC material 512 without etching the secondary material 513, such as to allow the TiC material 512 to remain for the pFET devices while the TiN remains for the nFET devices. Such as post etch state 507 is schematically shown in FIG. 5. To that end, the dry etching process 500 includes at least an oxidation step and a fluorination step as previously described, and may also include a substitution step, such as when M is included in the TiC material 512.

Conventional etching processes may use a wet etching technique, which suffers from various issues, such as poor etch stop at narrow features, aspect ratio dependent etch rate, and insufficient selectivity. As previously discussed, etching TiC materials such as TiMC materials selectively with respect to TiN may be desirable for various applications, including multi-Vt modulation in GAA devices, which FIG. 5 may schematically represent.

FIG. 6 schematically illustrates an example dry etching system that may be used to perform etching processes including at least an oxidation step and a fluorination step to etch TiC materials in situ within a processing chamber in accordance with embodiments of the invention. The dry etching system of FIG. 6 may be used to perform any of the methods and processes described herein, such as the dry etching processes of FIGS. 1-5 and the method of FIG. 7, for example. Similarly labeled elements may be as previously described.

Referring to FIG. 6, a dry etching system 600 (e.g., any suitable etching system that is configured to perform a dry etching process without the use of direct plasma) includes a processing chamber 670 configured to contain a substrate 610 (e.g., supported by a substrate holder 660), such as including a TiC material and a secondary material 113, such as TiN. An oxidation source 671 is fluidically coupled to the processing chamber 670. The oxidation source 671 may be an oxidizing gas source 672 (e.g., an O₃(g) source, an O₂(g) source, etc.). Alternatively, the oxidation source 671 may be a remote oxidizing plasma source 673 configured to generate an oxygen-containing plasma 662 (i.e., an indirect plasma not excited in the processing chamber 670), such as a remote O₂ plasma.

Similarly, a fluorination source 674 is also fluidically coupled to the processing chamber 670. The fluorination source 674 may be a fluorinating gas source 675 (e.g., an HF(g) source, a XeF₂(g) source, a SF₆(g) source, a SF₄(g) source, etc.). However, the fluorination source 674 may also be a remote fluorinating plasma source 676 configured to generate a fluorine-containing plasma 665, such as a remote SF₆ plasma.

Although not strictly necessary when a substitution step is not needed during a given etching process, the dry etching system 600 may also include a substitution gas source 677 fluidically coupled to the processing chamber 670, such as an Al₂(CH₃)₆(g) source, an H(acac)(g) source, and others. Additional gas sources may also be included in the dry etching system 600. For example, an optional additional gas source 678 may be fluidically coupled to the processing chamber 670 (an additional gas may be any type of gas, and multiple additional gases may be included). An exhaust valve 689 is also included to evacuate the processing chamber 670 during the etching process.

Various additional components may be included to facilitate control over different aspects of a given dry etching process. An optional temperature monitor 686 may be included to monitor and/or aid in controlling the temperature of the substrate 610 and the environment in the processing chamber 670. An optional temperature control device 687 may be included to raise or lower the temperature of the substrate 810 above or below the equilibrium temperature at the substrate 810 during the etching processes. Alternatively, the optional temperature control device 687 may be a cooler to decrease the temperature of the substrate 810 below equilibrium. An optional motor 688 may also be included to improve etching uniformity.

A controller 680 is operationally coupled to each of the oxidation source 671, the fluorination source 674, and the substitution gas source 677, and may be operationally coupled to any of the optional temperature monitor 686, the optional temperature control device 687, the optional motor 688, and the exhaust valve 689. The controller 680 includes a processor 682 and a memory 684 (i.e., a non-transitory computer-readable medium) that stores a program including instructions that, when executed by the processor 682, perform an etching process. For example, the memory 684 may have volatile memory (e.g., random access memory (RAM)) and non-volatile memory (e.g., flash memory). Alternatively, the program may be stored in physical memory at a remote location, such as in cloud storage. The processor 682 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 7 illustrates an example method of dry etching a TiC material in accordance with embodiments of the invention. The method of FIG. 7 may be combined with other methods and performed using the systems and apparatuses as described herein. For example, the method of FIG. 7 may be combined with any of the embodiments of FIGS. 1-6.

Referring to FIG. 7, a method 700 of dry etching a TiC material includes an oxidation step 701 and a fluorination step 702. In various embodiments, such as when the TiC material includes a secondary metallic component (a metallic species such as a metal or a metalloid), the method 700 may also include a substitution step 703. The method 700 may be performed as part of a cycle 708, such as in situ within a processing chamber, for example. The TiC material may be included in or on a substrate that also includes TiN. In this case, all steps (including the oxidation step 701, the fluorination step 702, the substitution step 703, and any additional steps such as purge steps) of the method 700 may be selective to the TiC material (relative to TiN).

The oxidation step 701 includes exposing the TiC material to an oxidizing agent to form an oxidized layer that includes TiOₓ species and also forms volatilized carbon oxide species that remove carbon from the TIC material. After the oxidation step 701, the TiOₓ species are exposed to a fluorinating agent during the fluorination step 702 to form volatilized TiOₓF_{y} species that remove titanium from the TiC material.

When the TiC material includes a metallic species, MOₙ species are also formed during the oxidation step 701, which are in turn fluorinated during the fluorination step 702 to form MFₙ species. The substitution step 703 may then be included after the fluorination step 702 to expose the expose the MFₙ species to a substitution agent to and remove the metallic species from the TiC material by forming volatilized MFₙ species. The metallic species is Al in one embodiment. In another embodiment, the metallic species is Si. In still another embodiment, the metallic species is La, but of course other metallic species may also be used.

The substitution agent introduced during the substitution step 703 is in the gas phase, and may be trimethylaluminum gas in one embodiment. The volatilized MFₙ species has a chemical formula of MFₐ(CH₃)_{b}(g) in one embodiment. In another embodiment, the substitution agent is a gaseous acetylacetone species and the metallic species is lanthanum (La).

One or more of the oxidizing agent and the fluorinating agent (in the oxidation step 701 and the fluorination step 702, respectively) may also be in the gas phase. For example, all steps of the cycle may be performed without plasma. For example, the oxidizing agent may be ozone gas O₃(g) and/or the fluorinating agent may be hydrogen fluoride gas HF(g). Alternatively, one or both the oxidizing agent and the fluorinating agent are partially or entirely in the plasma phase.

Example embodiments of the invention are summarized here. Other embodiments can also be understood from the entirety of the specification as well as the claims filed herein.

Example 1. A method of dry etching a titanium carbide material of a substrate, the method including performing a cycle in situ within a processing chamber, the cycle including: performing an oxidation step including exposing the titanium carbide material to an oxidizing agent to form an oxidized layer including TiOₓ species and remove carbon from the titanium carbide material by forming volatilized carbon oxide species; and performing a fluorination step including exposing the TiOₓ species of the oxidized layer to a fluorinating agent to remove titanium from the titanium carbide material by forming volatilized TiOₓF_{y} species.

Example 2. The method of example 1, where: the titanium carbide material includes a metallic species; the oxidized layer formed during the oxidation step further includes MOₙ species; the fluorination step further includes exposing the MOₙ species of the oxidized layer to the fluorinating agent to form MFₙ species; and the cycle further includes performing a substitution step including exposing the MFₙ species to a substitution agent to remove the metallic species from the titanium carbide material by forming volatilized MFₙ species.

Example 3. The method of one of examples 2 and 3, where the metallic species is aluminum (Al).

Example 4. The method of one of examples 2 and 3, where the substitution agent is in the gas phase.

Example 5. The method of example 4, where the oxidizing agent and the fluorinating agent are also in the gas phase, all steps of the cycle being performed without plasma.

Example 6. The method of one of examples 1 to 5, where the substrate further includes titanium nitride, all steps of the cycle being selective to the titanium carbide material of the substrate.

Example 7. A method of dry etching a titanium carbide material including titanium, carbon, and a metallic species, the method being performed in situ within a processing chamber and including: performing an oxidation step including exposing the titanium carbide material to an oxidizing agent to form an oxidized layer including TiOₓ species and MOₙ species, and remove carbon from the titanium carbide material by forming volatilized carbon oxide species; performing a fluorination step including exposing the TiOₓ species and the MOₙ species of the oxidized layer to a fluorinating agent to form MFₙ species and remove titanium from the titanium carbide material by forming volatilized TiOₓF_{y} species; and performing a substitution step including exposing the MFₙ species to a substitution agent to remove the metallic species from the titanium carbide material by forming volatilized MFₙ species.

Example 8. The method of example 7, where the substitution agent includes trimethylaluminum gas, the volatilized MFₙ species having a chemical formula of MFₐ(CH₃)_{b}(g).

Example 9. The method of example 8, where the metallic species is aluminum (Al).

Example 10. The method of example 8, where the metallic species is silicon (Si).

Example 11. The method of example 7, where the metallic species is lanthanum (La), and where the substitution agent includes a gaseous acetylacetone species.

Example 12. The method of one of examples 7 to 11, where the fluorinating agent is hydrogen fluoride gas.

Example 13. The method of one of examples 7 to 12, where the oxidizing agent is ozone gas.

Example 14. The method of one of examples 7 to 13, where the titanium carbide material is included by a substrate further including titanium nitride, the oxidation step, the fluorination step, and the substitution step all being selective to the titanium carbide material of the substrate.

Example 15. The method of example 14, further including: repeating the oxidation step, the fluorination step, and the substitution step as part of a cycle to continue etching the titanium carbide material.

Example 16. A dry etching system including: a processing chamber configured to contain a substrate including a titanium carbide material; an oxidation source fluidically coupled to the processing chamber and configured to supply an oxidizing agent into the processing chamber; a fluorination source fluidically coupled to the processing chamber and configured to supply a fluorinating agent into the processing chamber; and a controller operationally coupled to the oxidation source and the fluorination source, the controller including a processor and a non-transitory computer-readable medium storing a program including instructions that, when executed by the processor, perform a cycle in situ within the processing chamber, the cycle including an oxidation step including exposing the titanium carbide material to the oxidizing agent to form an oxidized layer including TiOₓ species and remove carbon from the titanium carbide material by forming volatilized carbon oxide species, and a fluorination step including exposing the TiOₓ species of the oxidized layer to the fluorinating agent to remove titanium from the titanium carbide material by forming volatilized TiOₓF_{y} species.

Example 17. The dry etching system of example 16, further including: a substitution source fluidically coupled to the processing chamber and the controller, the substitution source being configured to supply a substitution agent into the processing chamber; where the titanium carbide material includes a metallic species; where the oxidized layer formed during the oxidation step further includes MOₙ species; where the fluorination step further includes exposing the MOₙ species of the oxidized layer to the fluorinating agent to form MFₙ species; and where the cycle further includes performing a substitution step including exposing the MFₙ species to the substitution agent to remove the metallic species from the titanium carbide material by forming volatilized MFₙ species.

Example 18. The dry etching system of example 17, where the dry etching system is a gas phase dry etching system, each of the oxidation step, the fluorination step, and the substitution step being performed in the gas phase.

Example 19. The dry etching system of one of example examples 16 and 17, where the oxidation source is a remote plasma source, the oxidizing agent including species of an oxygen-containing plasma.

Example 20. The dry etching system of one of example examples 16 and 17, where the fluorination source is a remote plasma source, the fluorinating agent including species of a fluorine-containing plasma.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of dry etching a titanium carbide material of a substrate, the method comprising performing a cycle in situ within a processing chamber, the cycle comprising:
performing an oxidation step comprising exposing the titanium carbide material to an oxidizing agent to form an oxidized layer comprising titanium oxide (TiOₓ) species and remove carbon from the titanium carbide material by forming volatilized carbon oxide species; and
performing a fluorination step comprising exposing the TiOₓ species of the oxidized layer to a fluorinating agent to remove titanium from the titanium carbide material by forming volatilized TiOₓF_{y} species.

2. The method of claim 1, wherein:
the titanium carbide material comprises a metallic species;
the oxidized layer formed during the oxidation step further comprises oxidized metallic (MOₙ) species;
the fluorination step further comprises exposing the MOₙ species of the oxidized layer to the fluorinating agent to form metallic fluoride (MFₙ) species; and
the cycle further comprises performing a substitution step comprising exposing the MFₙ species to a substitution agent to remove the metallic species from the titanium carbide material by forming volatilized MFₙ species.

3. The method of claim 2, wherein the metallic species is aluminum (Al).

4. The method of claim 2, wherein the substitution agent is in the gas phase.

5. The method of claim 4, wherein the oxidizing agent and the fluorinating agent are also in the gas phase, all steps of the cycle being performed without plasma.

6. The method of claim 1, wherein the substrate further comprises titanium nitride, all steps of the cycle being selective to the titanium carbide material of the substrate.

7. A method of dry etching a titanium carbide material comprising titanium, carbon, and a metallic species, the method being performed in situ within a processing chamber and comprising:
performing an oxidation step comprising exposing the titanium carbide material to an oxidizing agent to form an oxidized layer comprising titanium oxide (TiOₓ) species and oxidized metallic (MOₙ) species, and remove carbon from the titanium carbide material by forming volatilized carbon oxide species;
performing a fluorination step comprising exposing the TiOₓ species and the MOₙ species of the oxidized layer to a fluorinating agent to form metallic fluoride (MFₙ) species and remove titanium from the titanium carbide material by forming volatilized TiOₓF_{y} species; and
performing a substitution step comprising exposing the MFₙ species to a substitution agent to remove the metallic species from the titanium carbide material by forming volatilized MFₙ species.

8. The method of claim 7, wherein the substitution agent comprises trimethylaluminum gas, the volatilized MFₙ species having a chemical formula of MFₐ(CH₃)_{b}(g).

9. The method of claim 8, wherein the metallic species is aluminum (Al).

10. The method of claim 8, wherein the metallic species is silicon (Si).

11. The method of claim 7, wherein the metallic species is lanthanum (La), and wherein the substitution agent comprises a gaseous acetylacetone species.

12. The method of claim 7, wherein the fluorinating agent is hydrogen fluoride gas.

13. The method of claim 7, wherein the oxidizing agent is ozone gas.

14. The method of claim 7, wherein the titanium carbide material is comprised by a substrate further comprising titanium nitride, the oxidation step, the fluorination step, and the substitution step all being selective to the titanium carbide material of the substrate.

15. The method of claim 14, further comprising:
repeating the oxidation step, the fluorination step, and the substitution step as part of a cycle to continue etching the titanium carbide material.

16. A dry etching system comprising:
a processing chamber configured to contain a substrate comprising a titanium carbide material;
an oxidation source fluidically coupled to the processing chamber and configured to supply an oxidizing agent into the processing chamber;
a fluorination source fluidically coupled to the processing chamber and configured to supply a fluorinating agent into the processing chamber; and
a controller operationally coupled to the oxidation source and the fluorination source, the controller comprising a processor and a non-transitory computer-readable medium storing a program including instructions that, when executed by the processor, perform a cycle in situ within the processing chamber, the cycle comprising
an oxidation step comprising exposing the titanium carbide material to the oxidizing agent to form an oxidized layer comprising titanium oxide (TiOₓ) species and remove carbon from the titanium carbide material by forming volatilized carbon oxide species, and
a fluorination step comprising exposing the TiOₓ species of the oxidized layer to the fluorinating agent to remove titanium from the titanium carbide material by forming volatilized TiOₓF_{y} species.

17. The dry etching system of claim 16, further comprising:
a substitution source fluidically coupled to the processing chamber and the controller, the substitution source being configured to supply a substitution agent into the processing chamber;
wherein the titanium carbide material comprises a metallic species;
wherein the oxidized layer formed during the oxidation step further comprises oxidized metallic (MOₙ) species;
wherein the fluorination step further comprises exposing the MOₙ species of the oxidized layer to the fluorinating agent to form metallic fluoride (MFₙ) species; and
wherein the cycle further comprises performing a substitution step comprising exposing the MFₙ species to the substitution agent to remove the metallic species from the titanium carbide material by forming volatilized MFₙ species.

18. The dry etching system of claim 17, wherein the dry etching system is a gas phase dry etching system, each of the oxidation step, the fluorination step, and the substitution step being performed in the gas phase.

19. The dry etching system of claim 16, wherein the oxidation source is a remote plasma source, the oxidizing agent comprising species of an oxygen-containing plasma.

20. The dry etching system of claim 16, wherein the fluorination source is a remote plasma source, the fluorinating agent comprising species of a fluorine-containing plasma.
